(19) United States
(12) Patent Application Publication
(10) Pub. No.: US 2006/0049846 A1
(43) Pub. Date: Mar. 9, 2006

(54) Input/output circuit operated by variable operating voltage

(76) Inventor: Hong-Joo Park, Chungcheongbuk-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/221,536

(22) Filed: Sep. 7, 2005

(30) Foreign Application Priority Data
Sep. 8, 2004 (KR) 2004-0071783

(51) Int. Cl. H03K 19/0175

(52) U.S. Cl. 326/68

(57) ABSTRACT

Disclosed herein is an input/output (I/O) circuit operated by a variable operating voltage for performing an input operation or an output operation with external chips by selecting one of two operating voltages. The I/O circuit operated by a variable operating voltage includes a middle level voltage generating unit for generating a middle level voltage between a high level operating voltage and a low level operating voltage by using a source-drain voltage of a MOS transistor; a voltage comparison unit for comparing the middle level voltage with an inputted external voltage to thereby output a comparison result; and an interface unit for performing an input operation or an output operation with the external chip by a selected operating voltage between the high level operating voltage and the low level operating voltage according to the comparison result of the voltage comparison unit.

### FIELD OF THE INVENTION

The present invention relates to an input/output circuit operated by a variable operating voltage; and, more particularly, to an input/output circuit operated by a variable operating voltage for performing an input operation or an output operation with the external chip by selecting one of two operating voltages.

### BACKGROUND OF THE INVENTION

In general, an input/output (I/O) circuit (hereinafter, referred to a multi-level I/O circuit) operated by a variable operating voltage is implemented in a semiconductor device for providing the same operating voltage level as an operating voltage level of an external chip connected to the semiconductor device.

The multi-level I/O circuit sets up a middle level voltage between a high and a low operating voltage of the external connected chip and the semiconductor device as a reference voltage and compares the reference voltage with an inputted operating voltage of the semiconductor device. Accordingly, it is possible to perform an input or an output operation between the external connected chip and the semiconductor device with the same operating voltage.

Hereinafter, for reference, detailed description is provided in the specification of the U.S. patent application, U.S. Pat. No. 5,534,801, filed on Jul. 9, 1996, entitled “APPARATUS AND METHOD FOR AUTOMATIC SENSE AND ESTABLISHMENT OF 5V AND 3.3V OPERATION”, which is incorporated herein by reference.

FIG. 1 is a block diagram showing a conventional semiconductor device having a multi-level I/O circuit.

As shown in FIG. 1, the multi-level I/O circuit controls an output level of the semiconductor device. Either a high level voltage V5 or a low level voltage V3 is carried on an external bus 116 via a bus connector 117 into the semiconductor device. Also, a middle level voltage generating unit 124 generates a middle level voltage V4 between the high level voltage V5 and the low level voltage V3. A voltage comparator 126 compares an inputted operating voltage V3/5 on the external bus 116 with the middle level voltage V4 generated by the middle level voltage generating unit 124 to thereby output the comparison result to an I/O cell 121.

If the inputted operating voltage V3/5 on the external bus 116 is greater than the middle level voltage V4, the voltage comparator 126 outputs a first digital signal onto a signaling-mode control line 123. Based on the first digital, the I/O cell 121 controls an OB buffer output 128o and an IB input 122i to be operated in a V5 signaling mode.

If the inputted operating voltage V3/5 on the external bus 116 is less than the middle level voltage V4, the voltage comparator 126 outputs a second digital signal onto the signaling-mode control line 123. Based on the second digital signal, the I/O cell 121 controls the OB buffer output 128o and the IB input 122i to be operated in a V3 signaling mode.

FIG. 2 is a block diagram showing the conventional middle level voltage generating unit 124 shown in FIG. 1.

As shown in FIG. 2, to generate the middle level voltage V4 between the low level voltage V3 and the high level voltage V5, the middle level voltage generating unit 124 includes a diode 201 and a resistor R.

The anode of diode 201 is connected with the chip-internal voltage V5 line while the cathode is connected with an end of the resistor R. The other end of the resistor R is connected with a chip-internal ground. If the diode 201 has a threshold voltage Vt, the middle level voltage generating unit 124 can generate the middle level voltage V4 by deducting the diode voltage Vt from V5.

However, in the conventional invention, it is possible to generate the middle level voltage only if a difference between the high and the low operating voltage is more than twice of the diode threshold voltage Vt.

Moreover, a power consumption is increased due to the resistor R.

### SUMMARY OF THE INVENTION

It is, therefore, an object of the present invention to provide a multi-level I/O circuit for being applicable in a case that a difference between a high and a low operating voltage is not only more than twice of the diode threshold voltage Vt but also less than twice of the diode threshold voltage Vt.

It is, therefore, another object of the present invention to provide a multi-level I/O circuit for being applicable to a semiconductor device operated under a low power limitation by reducing power consumption occurred due to a resistor.

In an aspect of the present invention, there is provided an I/O circuit operated by a variable operating voltage, including: a middle level voltage generating unit for generating a middle level voltage between a high level operating voltage and a low level operating voltage by using a source-drain voltage of a MOS transistor; a voltage comparison unit for comparing the middle level voltage with an inputted external voltage to thereby output a comparison result; and an interface unit for performing an input operation or an output operation with the external chip by a selected operating voltage between the high level operating voltage and the low level operating voltage according to the comparison result of the voltage comparison unit.

In another aspect of the present invention, there is provided a middle level voltage generating circuit, including: an operating control unit for controlling an operation according to an operating signal; and a voltage generating unit for generating a middle level voltage by deducting a source-drain voltage of a MOS transistor from a high level operating voltage, wherein the operating control unit is coupled to the voltage generating unit via a current mirror using MOS transistors.

In a further another aspect of the present invention, there is provided a voltage comparison circuit, including: an input unit for receiving a reference voltage and an external voltage; an amplifying unit including a pair of cross-coupled MOS transistors for amplifying and latching a difference between the reference voltage and the external voltage; an output unit for outputting a logic value determined by a result of comparing the reference voltage with the external voltage; and an operating control MOS transistor located at an outflow path of an operating current of the input unit and amplifying unit for controlling a voltage comparison unit by transferring an operating signal through gates.

### BRIEF DESCRIPTION OF THE DRAWINGS

The above and other objects and features of the present invention will become apparent from the following description of preferred embodiments given in conjunction with the accompanying drawings, in which:

FIG. 1 is a block diagram showing a conventional semiconductor device having a multi-level I/O circuit;

FIG. 2 is a block diagram showing a middle level voltage generating unit for use in the multi-level I/O circuit shown in FIG. 1;

FIG. 3 is a block diagram illustrating an external connection of a semiconductor device having a multi-level I/O circuit in accordance with an embodiment of the present invention;

FIG. 4 is a block diagram depicting a middle level voltage generating unit for use in the multi-level I/O circuit shown in FIG. 3 in accordance with the present invention; and

FIG. 5 is a block diagram describing a voltage comparison unit for use in the multi-level I/O circuit shown in FIG. 3 in accordance with the present invention.

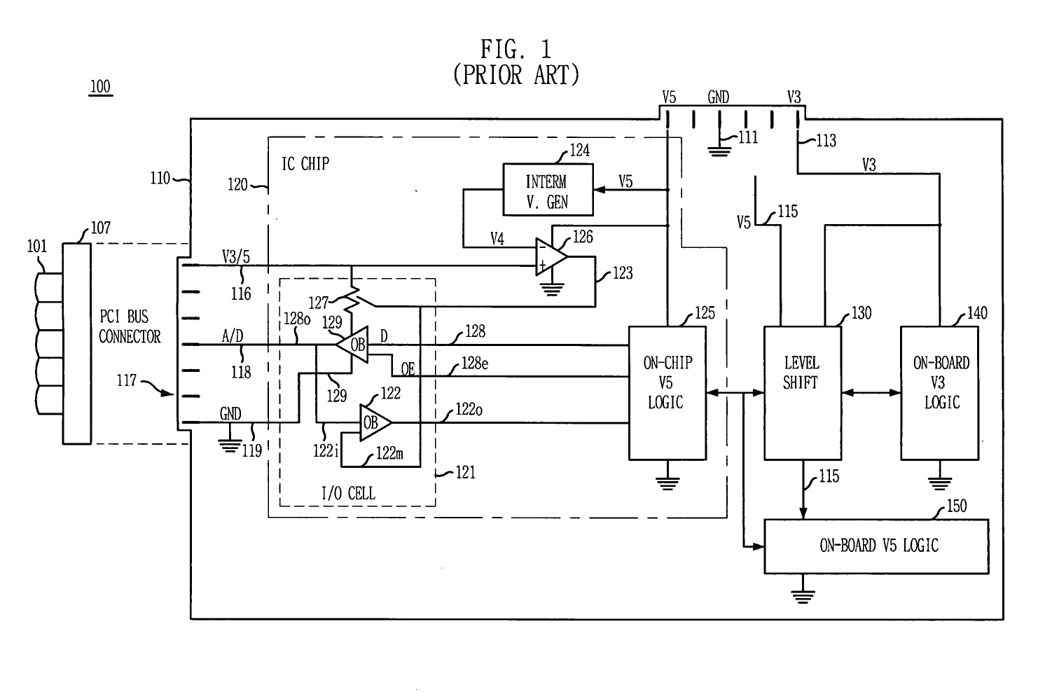

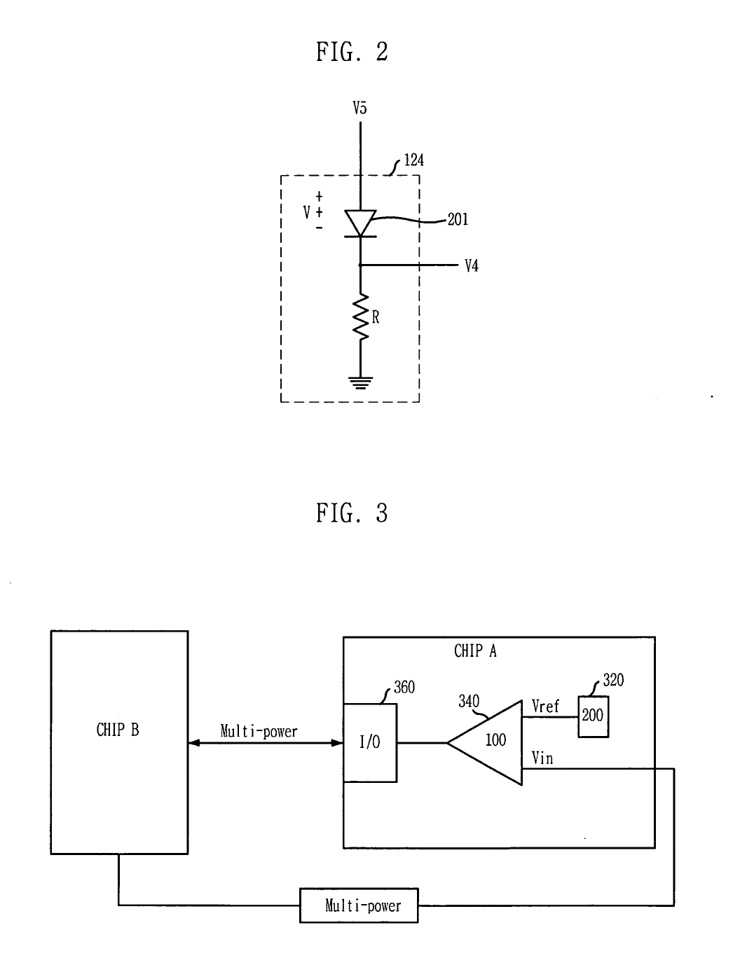

### DETAILED DESCRIPTION OF THE PREFERRED EMBODIMENTS

Hereinafter, a multi-level I/O circuit in accordance with the present invention will be described in detail referring to the accompanying drawings.

FIG. 3 is a block diagram illustrating an external connection of a semiconductor device having a multi-level I/O circuit in accordance with an embodiment of the present invention.

Hereinafter, the multi-level I/O circuit is applicable to all semiconductor devices having an input or output signal bus such as an address bus or a data bus. Particularly, the multi-level I/O circuit is effective to an image sensor device whose an operating voltage of an external data bus is about 1.8 V or 2.8 V.

For example, the multi-level I/O circuit according to an embodiment of the present invention can be described as being used for a low level voltage circumstance, e.g., a 1.8 V circumstance, or a high level voltage circumstance, e.g., a 2.8 V circumstance.

Referring to FIG. 3, the multi-level I/O circuit includes a middle level voltage generating unit 320, a voltage comparison unit 340 and an interface unit 360. The middle level voltage generating unit 320 generates a middle level voltage between a high level voltage and a low level voltage, using a source-drain voltage of a MOS transistor. The voltage comparison unit 340 compares the middle level voltage with an operating voltage inputted from an external chip to thereby output the compared result to the interface unit 360. The interface unit 360 is for performing an input operation from or an output operation to the external chip with one of the high and the low level voltages according to the comparison result outputted from the voltage comparison unit 340.

The multi-level I/O circuit adjusts an operating voltage level to one of the high and the low level voltages, e.g., a 1.8 V or a 2.8 V, based on a voltage level of an input or an output signal inputted to or outputted from the external chip. Accordingly, it is possible to perform the input or the output operation between the external chip and the semiconductor device with the same operating voltage.

The middle level voltage generating unit 320 generates a reference voltage Vref having the middle level voltage value between about the 1.8 V and about the 2.8 V. It is desirable for the reference voltage Vref to be about a 2.3 V.

The voltage comparison unit 340 compares the reference voltage Vref with the voltage inputted from the external chip. Then, the voltage comparison unit 340 outputs a logic value of the comparison result. If the reference voltage Vref is higher than the external voltage, the voltage comparison unit 340 outputs a logic high level ‘1’. If the external voltage is higher than the reference voltage Vref, the voltage comparison unit 340 outputs a logic low level ‘0’. Herein, the external voltage means the voltage level of an input or an output signal inputted to or outputted from the external chip connected to a data or an address bus for performing input or the output operation between the external connected chip and the semiconductor device with the same operating voltage. Because general semiconductor devices use a power source voltage level as the voltage level of an input or an output signal, the power source voltage level of the external chip mainly is used for the external voltage.

The interface unit 360 performs the input operation or the output operation with the external chip according to the logic value of the voltage comparison unit 340. If the logic value of the voltage comparison unit 340 is ‘1’, the interface unit 360 performs the input operation from or the output operation to the external chip with a 2.8 V operating voltage. If the logic value of the voltage comparison unit 340 is ‘0’, the interface unit 360 performs the input operation from or the output operation to the external chip with a 1.8 V operating voltage.

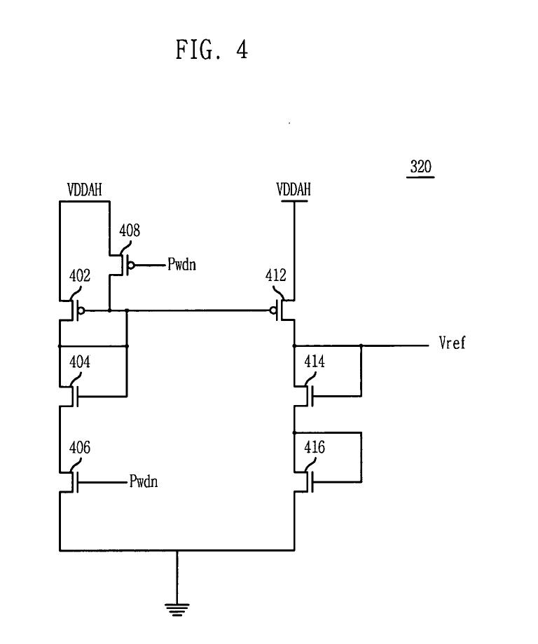

FIG. 4 is a block diagram depicting a middle level voltage generating part for use in the multi-level I/O circuit shown in FIG. 3 in accordance with the present invention.

Referring to FIG. 4, the middle level voltage generating unit 340 includes an operating control unit and a voltage generating unit.

The operating control unit includes a mirror PMOS transistor 402, a first operating control NMOS transistor 404, a second operating control NMOS transistor 406 and a first PMOS transistor 408. The mirror PMOS transistor 402 forms a current mirror with a middle level voltage controlling PMOS transistor 412 of the voltage generating unit. The first operating control NMOS transistor 404, the second operating control NMOS transistor 406 and the first PMOS transistor 408 are for controlling an operation of the middle level voltage generating unit 320 according to an operating signal Pwdn. Herein, the mirror PMOS transistor 402 and the middle level voltage controlling PMOS transistor 412 are connected with the current mirror. So, when a current flows on the operating control unit, the same current also flows on the voltage generating unit.

The voltage generating unit includes the middle level voltage controlling PMOS transistor 412 for generating the middle level voltage deducting the source-drain voltage of the MOS transistor from the high level voltage and a diode block including a first diode-connected NMOS transistor 414 and a second diode-connected NMOS transistor 416 to maintain a voltage gap between the middle level voltage and a ground voltage. The voltage generating unit can generate about the 2.3 V voltage level as the middle level voltage between the 2.8 V and the 1.8 V by controlling a W/L ratio of the middle level voltage controlling PMOS transistor 412, the first diode-connected NMOS transistor 414 and the second diode-connected NMOS transistor 416.

Namely, according to the conventional invention, the middle level voltage is generated by a diode connected MOS transistor. In this case, the middle level voltage can be generated by deducting a threshold voltage of the MOS transistor, i.e., gate-drain or gate-source voltage, from the high level voltage. However, it is hard to control the threshold voltage owing to characteristics of MOS transistor.

On the other hand, according to the present invention, the middle level voltage can be generated by deducting the source-drain voltage of the MOS transistor from the high level voltage. Accordingly, it is easy to control the voltage difference between the high level voltage and the middle level voltage by controlling the W/L ratio of the MOS transistors.

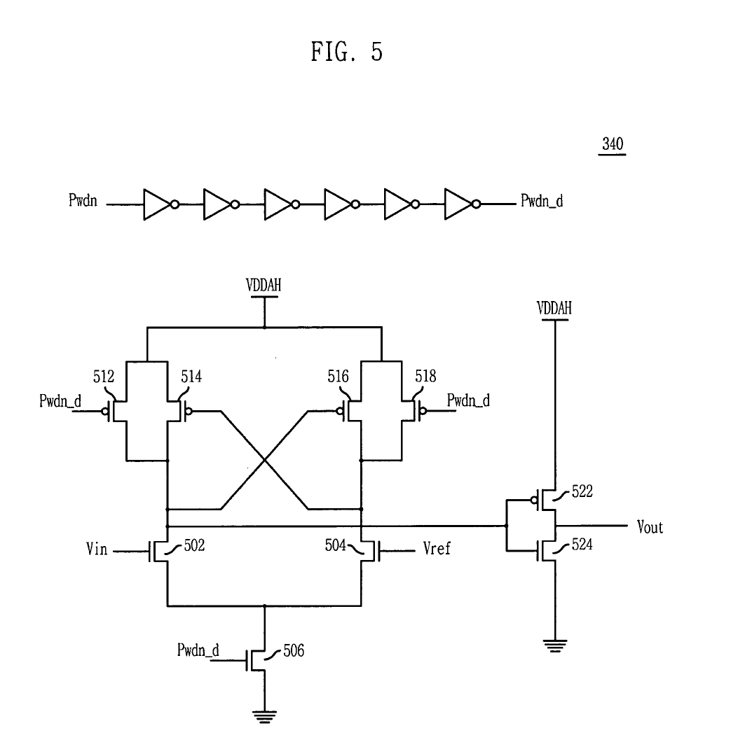

FIG. 5 is a block diagram describing a voltage comparison part 340 for use in the multi-level I/O circuit shown in FIG. 3 in accordance with the present invention.

Referring to FIG. 5, the voltage comparison unit 340 includes an input unit for receiving a middle level voltage (a reference voltage) and an external voltage, an amplifying unit for amplifying a difference between the reference voltage and the external voltage, an output unit for outputting a stable output voltage and an operating signal delaying unit for delaying an operating signal.

The input unit includes a first input NMOS transistor 504 for receiving the reference voltage Vref by gate and a second input NMOS transistor 502 for receiving the external voltage Vin by gate. The input unit generates a drain voltage of the first input NMOS transistor 504 in inverse proportion to the reference voltage Vref and a drain voltage of the second input NMOS transistor 502 in inverse proportion to the external voltage Vin.

The amplifying unit includes a pair of cross-coupled PMOS transistors 514 and 516 to thereby amplify a difference between the drain voltage of the second input NMOS transistor 502 and the drain voltage of the first input NMOS transistor 504. A pair of reset PMOS transistors 512 and 518, connected to the pair of cross-coupled PMOS transistors 514 and 516 in parallel, and a first NMOS transistor 506 on a current outflow path are for controlling an operation of the voltage comparison unit 340 according to a delay operating signal Pwdn_d.

The output unit converts a result value of the amplifying unit into a logic value and outputs a sufficient power. The output unit of the present invention includes an inverter which is constituted with a pair of gate-connected MOS transistors 522 and 524.

The operating signal delaying unit is for generating the delay operating signal Pwdn_d by delaying the operating signal Pwdn for a predetermined time. The operating signal delaying unit of the present invention includes plural inverters.

Henceforth, a use of the delay operating signal Pwdn_d and the operating signal Pwdn is described.

The reason why the operating signal Pwdn is used for the middle level voltage generating unit 320 and the delay operating signal Pwdn_d, generated by delaying the operating signal Pwdn for the predetermined time to thereby have the same phase as that of the operating signal Pwdn, is used for the voltage comparison unit 340 is a memory function of a latch structure.

If the operating signal Pwdn is inputted to both the middle level voltage generating unit 320 and the voltage comparison unit 340, both the middle level voltage generating unit 320 and the voltage comparison unit 340 are activated at the same time. Then, before the middle level voltage of the middle level voltage generating unit 340 become a stable reference voltage having about 2.3 V, the voltage comparison unit 340 recognizes a voltage level at an initial unstable state as the middle level voltage. So, though the stable reference voltage having about 2.3 V is inputted to the voltage comparison unit 340, desirable outputs cannot be generated.

To prevent the above, in present invention, the delay operating signal Pwdn_d is inputted to the voltage comparison unit 340. Accordingly, the middle level voltage generating unit 320 is activated first, and then the middle level voltage is set up to the stable reference voltage having about 2.3 V before the voltage comparison unit 340 is activated. Therefore, a normal operation can be guaranteed.

Further, because the voltage comparison unit 340 of the present invention has a latch structure including the pair of cross-coupled MOS transistors, the voltage comparison unit 340 can save an output value. Also, though an initial power consumption is relatively large, an overall power consumption becomes small and an operation speed of the voltage comparison unit 340 is dramatically increased.

Furthermore, by controlling a W/L ratio of the first NMOS transistor 506 and an amount of current flowing in the voltage comparison unit 340, a voltage comparator for a low power consumption is possible. At the same time, the voltage comparison unit 340 is controlled by the delay operating signal Pwdn_d inputted to the gate of the first NMOS transistor 506. Also, by the delay operating signal Pwdn_d inputted to the gate of the pair of the reset PMOS transistors 512 and 518, it is possible to reset the amplifying unit of the voltage comparison unit 340 on power-off.

The output logic value of the voltage comparison unit 340 is inputted to the interface unit 360. When the logic value is ‘1’, the interface unit 360 controls switches and driving current so as to make a voltage level of the input or output signal be about the 2.8 V. When the logic value is ‘0’, the interface unit 360 controls switches and a driving current so as to make the voltage level of the input or output signal be about the 1.8 V.

Hereinafter, it is assumed that the multi-level I/O circuit shown in FIGS. 3 to 5 is applied to a cellular phone having a CMOS image sensor.

Generally, the CMOS image sensor needs a low power consumption. Hence, the voltage comparison unit 340 controls the W/L ratio of the first NMOS transistor 506 on the current outflow path so that the current flows as smaller as possible. Also, with the delay operating signal Pwdn_d, the voltage comparison unit 340 can supply general signals which control whole operation of the CMOS image sensor device.

Assume that a chip A in FIG. 3 is the CMOS image sensor and a chip B in FIG. 3 is a baseband chip for performing an input operation or an output operation with the chip A. Generally, the chip B operates at the 1.8 V or the 2.8 V. From a production cost point of view, it is desirable to implement the chip B for a general-purpose chip which can operate at the 1.8 V or the 2.8 V so as to be connected with any external chips. Therefore, the multi-level I/O circuit of the present invention can be used.

A multi-power supplying block shown in FIG. 3 is an output voltage of the cellular phone. The multi-power supplying block provides the chip B with a power source voltage. Also, the multi-power supplying block provides the chip A with an external voltage Vin used for the voltage comparison unit 340 in the chip A, not a power source voltage.

As described above, the multi-level I/O circuit can be applicable to a semiconductor device operated under a low power limitation by reducing power consumption. Also, the multi-level I/O circuit can be applicable in a case that a difference between a high and a low voltages is not only more than twice of the diode threshold voltage Vt but also less than twice of the diode threshold voltage Vt.

The present application contains subject matter related to Korean patent application No. 2004-71783, filed in the Korean Patent Office on Sep. 8, 2004, the entire contents of which being incorporated herein by reference.

While the present invention has been described with respect to the particular embodiments, it will be apparent to those skilled in the art that various changes and modifications may be made without departing from the spirit and scope of the invention as defined in the following claims.

What is claimed is:

1. An input/output (I/O) circuit operated by a variable operating voltage, comprising:
a middle level voltage generating unit for generating a middle level voltage between a high level operating voltage and a low level operating voltage by using a source-drain voltage of a MOS transistor; and
a voltage comparison unit for comparing the middle level voltage with an inputted external voltage to thereby output a comparison result.

2. The I/O circuit as recited in claim 1, further comprising an interface unit for performing an input operation or an output operation with the external chip by a selected operating voltage between the high level operating voltage and the low level operating voltage according to the comparison result of the voltage comparison unit.

3. The I/O circuit as recited in claim 1, wherein the middle level voltage generating unit includes:
a voltage generating unit for generating the middle level voltage by deducting the source-drain voltage of the MOS transistor from the high level operating voltage; and
an operating control unit for controlling an operation of the voltage generating unit according to an operating signal.

4. The I/O circuit as recited in claim 3, wherein the operating control unit and the voltage generating unit are connected with a current mirror using MOS transistors.

5. The I/O circuit as recited in claim 3, wherein the voltage generating unit includes:
a middle level voltage controlling MOS transistor for generating the middle level voltage which deducts the source-drain voltage of the MOS transistor from the high level voltage; and
a diode block including one or more diodes to maintain a voltage gap between the middle level voltage and a ground voltage.

6. The I/O circuit as recited in claim 5, wherein the operating control unit includes:
a mirror MOS transistor, corresponding with the middle level voltage controlling MOS transistor, for forming a current mirror; and
one or more operating control MOS transistors for controlling an operation according to the operating signal.

7. The I/O circuit as recited in claim 1, wherein the voltage comparison unit is controlled by a delay operating signal which delays the operating signal for a predetermined time.

8. The I/O circuit as recited in claim 1, wherein the voltage comparison unit includes:
an input unit for receiving the middle level voltage and the external voltage;
an amplifying unit for amplifying a difference between the middle level voltage and the external voltage; and
an output unit for outputting a logic value, which is calculated as a comparison result between the middle level voltage and the external voltage.

9. A middle level voltage generating circuit, comprising:
an operating control unit for controlling an operation according to an operating signal; and
a voltage generating unit for generating a middle level voltage by deducting a source-drain voltage of a MOS transistor from a high level operating voltage,
wherein the operating control unit is coupled to the voltage generating unit via a current mirror using MOS transistors.

10. The middle level voltage generating circuit as recited in claim 9, wherein voltage generating unit includes:
a middle level voltage controlling MOS transistor for generating the middle level voltage deducting the source-drain voltage of the MOS transistor from the high level voltage; and
a diode block including one or more diodes to maintain a voltage gap between the middle level voltage and a ground voltage.

11. The middle level voltage generating circuit as recited in claim 10, wherein the operating control unit includes:
a mirror MOS transistor, corresponding with the middle level voltage controlling MOS transistor, for forming a current mirror; and
one or more operating control MOS transistors for controlling the operation according to the operating signal.

12. A voltage comparison circuit, comprising:
an input unit for receiving a reference voltage and an external voltage;
an amplifying unit including a pair of cross-coupled MOS transistors for amplifying and latching a difference between the reference voltage and the external voltage;
an output unit for outputting a logic value determined by a result of comparing the reference voltage with the external voltage; and
an operating control MOS transistor located at an outflow path of an operating current of the input unit and amplifying unit for controlling a voltage comparison unit by transferring an operating signal through gates.

13. The voltage comparison circuit as recited in claim 12, wherein the operating control MOS transistor has smaller W/L ratio so as to flow a small operating current.

14. The voltage comparison circuit as recited in claim 12, wherein the output unit includes an inverter composed of a pair of MOS transistors.

15. The voltage comparison circuit as recited in claim 12, further comprising a pair of reset MOS transistors, connected with the pair of cross-coupled MOS transistors in parallel, respectively, for resetting the amplifying unit by inputting the operating signal through gates.

16. The voltage comparison circuit as recited in claim 12, further comprising an operating signal delaying unit for generating the operating signal by delaying an inputted external operating signal for a predetermined time.
